(19) United States
(12) Patent Application Publication
(10) Pub. No.: US 2007/0123191 A1
(43) Pub. Date: May 31, 2007

(54) Human-machine interface for a portable electronic device

(76) Inventor: Andrew Simpson, Basingstoke (GB)

Correspondence Address: MOTOROLA, INC., 1303 EAST ALGONQUIN ROAD, IL01/3RD, SCHAUMBURG, IL, 60196, US

(21) Appl. No.: 11/266,100

(22) Filed: Nov. 3, 2005

(51) Int. Cl. H05K 11/02; H04B 1/06

(52) U.S. Cl. 455/345

(57) ABSTRACT

A vehicle interface unit (220) provides a voice recognition-based human-machine interface for a portable electronic device (210) such as a portable digital assistant or a laptop computer in a vehicle. The interface unit (220) may be configured to provide run-time implementation of new PDA applications by transferring menu configuration files associated with the application from the PDA (210) to the interface unit (220).

### FIELD OF INVENTION

The present invention relates to interfaces for electronic devices. In particular, this invention relations to a human-machine-interface for a portable electronic device in a vehicle environment.

### BACKGROUND OF THE INVENTION

Portable electronic devices, such as portable digital assistants (PDA's), are increasingly providing applications which users may want to use while in the vehicle. To allow such applications to be used while driving, a voice recognition (VR) based system is required. Vehicles are increasingly including VR functionality. Currently, however, it may not be possible to use this feature to control the applications on the portable electronic device. The vehicle VR menus are typically fixed at production and only allow existing vehicle based applications to be controlled. These portable electronic device applications are, however, numerous and not necessarily known when the vehicle is designed so this system must work without requiring prior knowledge of the portable electronic device applications.

Thus, a need exists for an interface between a portable electronic device and a vehicle environment that is easily updatable and convenient for a driver to use.

### BRIEF DESCRIPTION OF THE DRAWINGS

Embodiments of the present invention are now described, by way of example only, with reference to the accompanying figures in which:

FIG. 1 is a schematic of a voice recognition based human-machine-interface.

FIG. 2 is a more detailed schematic of a voice recognition based human-machine interface.

FIG. 3 illustrates an example of steps to implement a vehicle voice recognition system as a human-machine interface for a portable electronic device.

FIG. 4 illustrates a further example of steps to implement a vehicle voice recognition system as a human-machine interface for a portable electronic device.

### DETAILED DESCRIPTION OF THE INVENTION

The invention provides a vehicle voice recognition (VR) system as a human-machine interface (HMI) for a portable electronic device, such as a personal digital assistant or laptop computer within a vehicle. The system allows run-time implementation of applications through a vehicle interface unit that were not pre-installed with the vehicle. The system may include, but is not limited to, a vehicle interface unit with a VR system and a graphical display, a portable electronic device where the supported applications are stored and executed, and a source of verbal commands that allow control of the portable electronic device through the vehicle interface unit. The system may allow the vehicle interface unit to be configured at run-time for new applications stored on the portable electronic device through the transfer and installation of new menu configuration files to the interface unit.

A method for interfacing a portable electronic device with a vehicle interface unit may include the steps of configuring the vehicle interface unit to support adding new menus based on new supported applications on the portable electronic device, connecting the portable electronic device to the vehicle interface unit, selecting a supported application on the portable electronic device, sending and installing menu configuration files associated with the application to the vehicle interface unit, and sending verbal commands to the interface unit to control the portable electronic device.

To allow a portable electronic device or other external device to use the VR and text-to-speech (TTS) provided by the vehicle to access applications and data stored on the remote portable electronic device, it may be necessary to provide a mechanism which allows the VR menus and prompts to be tailored to suit the portable electronic device application. A vehicle VR-based HMI may provide a standard text-based menu/prompt definition format which could be downloaded to the VR system at run time and which would allow the menus/prompts to be customized. A utility in the portable electronic device may download the appropriate VR menu file based on the currently selected application. The vehicle VR system would need no prior knowledge of the portable electronic device application and would only need to store one custom VR menu at a time (as the portable electronic device would download the required menu whenever a new portable electronic device application was activated). Let us now refer to the figures that illustrate embodiments of the present invention in detail.

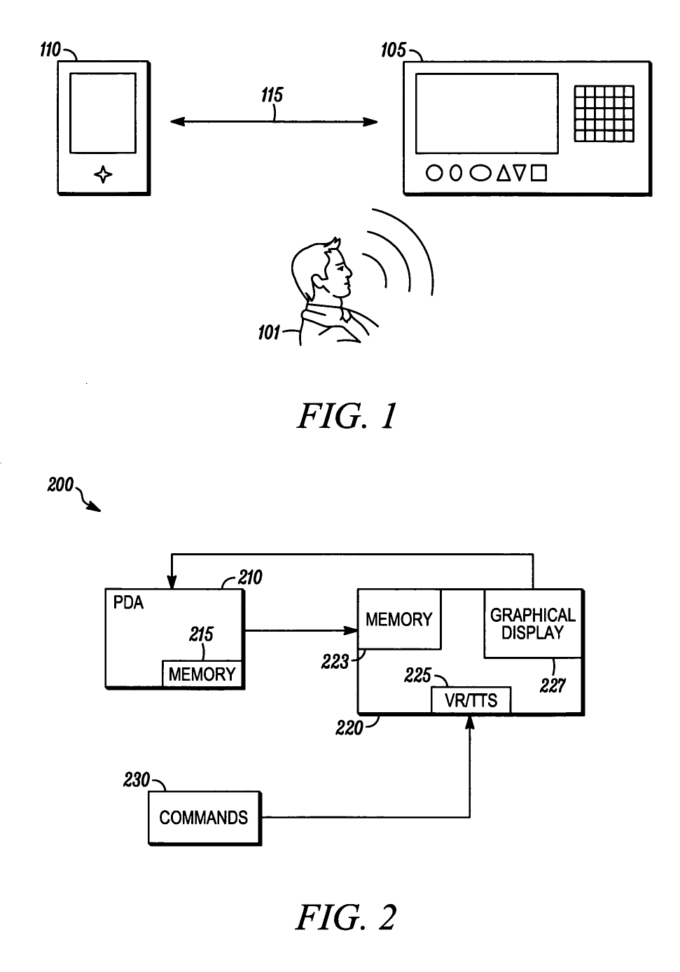

FIG. 1 illustrates components to implement a VR system as a HMI for a portable electronic device. A user 101 may be located in a vehicle environment, whether as a driver or a passenger in the vehicle. A vehicle interface unit 105 is provided within the vehicle to accept commands from the user 101. The vehicle interface unit 105 may be located anywhere within the vehicle, as long as the vehicle interface unit 105 is within range of the user's voice to register any verbal commands uttered by the user 101. A portable electronic device 110 is also provided with the system. The portable electronic device 110 may also be located within the vehicle, and in communication through a connection 115 with the vehicle interface unit 105. The portable electronic device 110 may be connected to the vehicle interface unit 105 through a wired connection. Examples of wired interface include, but are not limited to, coaxial cable, USB, serial, RCA or other wired connection interfaces. The portable electronic device 110 may also be connected to the vehicle interface unit 305 with a wireless connection. Examples of wireless connections include, but are not limited to, WiFi, Bluetooth, IrDA, radio, or other wireless connections protocols. The portable electronic device 110 may be located in a cradle or similar interface which communicates with the vehicle interface unit 105. The portable electronic device 110 may be in the form of a personal digital assistant, cellular telephone, personal communication device, laptop computer, or other portable devices capable of supporting applications. The portable electronic device 110 may support applications such as, but not limited to, navigation, trip planning, address and calendar applications, entertainment, reference, personal organizer, and other applications. Both the portable electronic device 110 and the vehicle interface unit 105 may provide visual displays and/or audio outputs.

FIG. 2 illustrates the components of FIG. 1 in greater detail. The HMI system 200 may include a portable electronic device 210, a vehicle interface unit 220, and a source of verbal input commands 230. The portable electronic device 210 may include a memory 215 for storing information such as menu configuration files, application and system software, and other user data. The memory 215 may be integrated within the portable electronic device 210, or may be a separate unit, such as a memory card or an external memory storage unit. Examples of memory 215 may include non-volatile memory cards, hard disk storage, disc-based media such as CD, floppy disk, or DVD, or volatile memory components.

The vehicle interface unit 220 may include a memory 223, a voice recognition unit 225, and a graphical display 227. The memory 223 may be integrated within the vehicle interface unit 220, or may be a separate unit such as a memory card or an external memory storage unit. Examples of memory 223 may include non-volatile memory cards, hard disk storage, disc-based media such as CD, floppy disk, or DVD, or volatile memory components.

The vehicle interface unit 220 may include a VR unit 225 for accepting verbal commands from a source of verbal commands 230. The VR unit 225 may include a microphone for receiving voice commands, an analog-to-digital-converter (ADC) unit, and software necessary to convert voice commands to digital signals capable of use by the VR unit 225. The VR unit 225 may also include software for implementing a text-to-speech (TTS) interface so that verbal commands to enhance the ability of the vehicle interface unit 220 to provide flexible prompts and feedback to the user. The VR unit 225 may include other applications encoded in a computer readable medium for use in processing verbal commands. The VR unit 225 is therefore expandable and adaptable to improving technologies and growing verbal command libraries. The VR unit 225 may support run-time addition of one or more new menus contained in the menu configuration file transferred from the portable electronic device 210. The menu configuration files are associated with an application supported and running on the portable electronic device 210. The menu configuration file implements the command interface functions necessary to allow integration of the vehicle interface unit 220 with the portable electronic device 210, and allow the control of the portable electronic device 210 by the vehicle interface unit 220 through a user's verbal commands 230.

The vehicle interface unit 220 may also include a visual display 227. The visual display 227 may be used to display information of interest to a user. For example, the vehicle interface unit may include a radio, navigation, and/or disc player. The visual display 227 may display direction and routing information, vehicle information, radio or stored media information, or other pertinent visual information. In addition, the visual display 227 may be configured to echo the verbal commands executed by the portable electronic device 210, in a graphical manner, such as through a text translation of the verbal commands. This command echo allows confirmation by the user that the command was accepted by the portable electronic device 210, as the portable electronic device 210 may not be in visual range of the user, or may itself not provide a confirmation of acceptance of the verbal command.

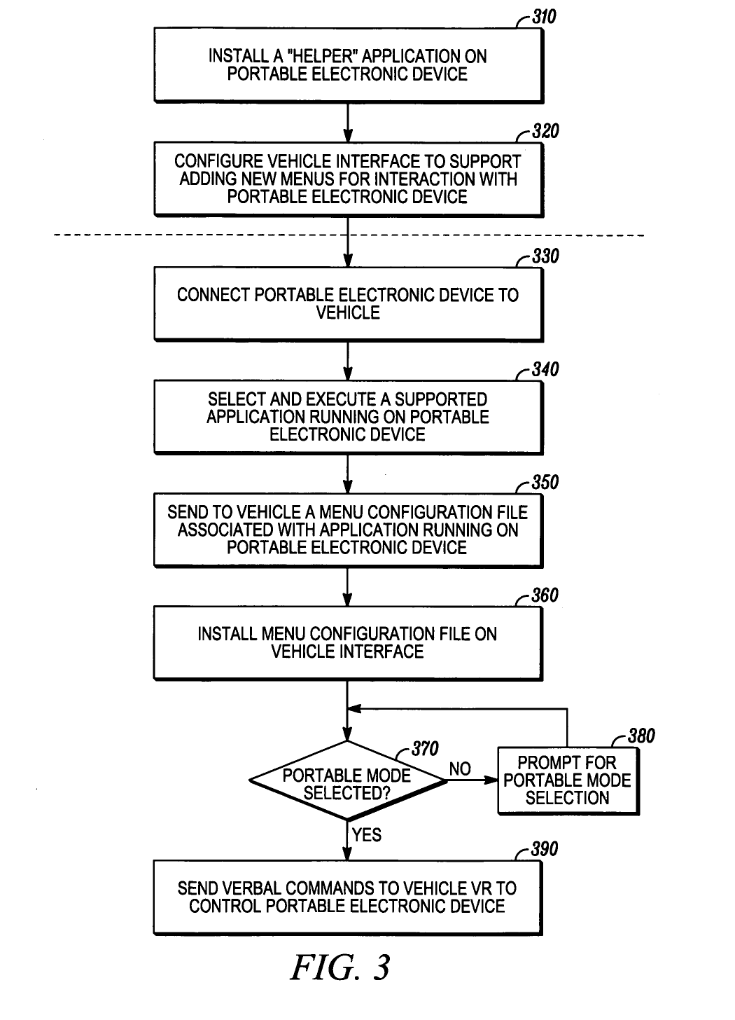

FIG. 3 illustrates an example of one embodiment of the present invention where steps are taken to implement a vehicle VR system as an HMI for a portable electronic device. As preliminary steps, a vehicle interface unit 220 and a portable electronic device 210 may be provided. A helper application, at step 310, may be installed on the portable electronic device. The helper application may be required to support portable electronic device applications, stored on the portable electronic device, which are not already designed to work with this vehicle interface unit, so that the helper application allows the portable electronic device to function as a helper device. In a typical embodiment, the helper application is an interface adaptor which may provide translation between a standardized interface which may be specified between the portable electronic device and the vehicle, and the non-standard interface provided by the portable electronic device application stored on the portable electronic device. Examples of helper applications may include, but are not limited to, platform-translating software, communication interface software, compiling and run-time execution software that may be needed to enable PDA applications to work with the vehicle interface unit.

The vehicle interface unit 220 may be configured, at step 320, to support adding new menus for interaction with the portable electronic device 210. The portable electronic device 210 may be connected, at step 330, to the vehicle. The portable electronic device 210 may be connected via a wired connection such as through a serial or USB connection. The portable electronic device 210 may also be connected through a wireless connection, such as Bluetooth, WiFi, or IRDA connections. The portable electronic device 210 may be mounted in the vehicle, such as on a console, dashboard, or seat, or may remain free-standing.

To interact with the vehicle interface unit 220, a user selects, at step 340, a supported application on the portable electronic device 210. The interface unit 220 then executes the supported application. The user may select the supported application through a user interface on the portable electronic device via tactile buttons on the portable electronic device, through a wireless interface, a remote control, a wireless key fob, voice recognition on the portable electronic device 210 or a wired control mechanism connected to the portable electronic device. Examples of supported applications may include, but not limited to, navigation, mapping, address book or calendar applications, music, productivity, reference applications, or other applications available on the portable electronic device.

The portable electronic device 210 sends, at step 350, a menu configuration file associated with the supported application. A menu configuration file may provide instructions for the vehicle interface unit 220 to provide and/or display menus accessible to a user for interaction with the vehicle interface unit. The menu configuration file may implement the same functionality on the vehicle interface unit 220 that is available on the portable electronic device 210. The portable electronic device 210 may send a menu configuration file only when a new supported application is loaded on the portable electronic device 210. The vehicle interface unit 220 installs, at step 360, the menu configuration file sent from the portable electronic device 210. The vehicle interface unit 220 may determine, at step 370, if a “portable mode” has been selected. A portable mode of operation is a mode of operation implemented by the vehicle interface unit 220 which allows the use of a portable electronic device 210 to work with the vehicle interface unit 220. The operation of the vehicle interface unit 220 may vary depending on the type of vehicle and what types of functions are enabled. For example, the vehicle interface unit 220 may lock out other functions of the vehicle interface unit 220 when in portable mode, or the vehicle interface unit 220 may provide a visual or audible indicator to let a user know the vehicle interface unit 220 is in portable mode. The vehicle interface unit 210 may enable a different user interface during portable mode, including any changes required by the loaded menu configuration file.

If a portable mode has been selected, the vehicle interface unit 220 may prompt the user, at step 390, to send verbal commands to the vehicle interface unit 220 to control the portable electronic device 210. If a portable mode has not been selected, the vehicle interface unit 220 prompts the user, at step 380, to select a portable mode. The vehicle interface unit 220 may prompt the user with an audible alert or through a visual signal, or a combination of visible and audible signals. The user may select the portable mode by actuating a button on the vehicle interface unit 220, by actuation of a button on the steering wheel or other location in the vehicle, or through a verbal signal directed to the vehicle interface unit 220. Such verbal signals may include commands pre-configured in the vehicle interface unit 220.

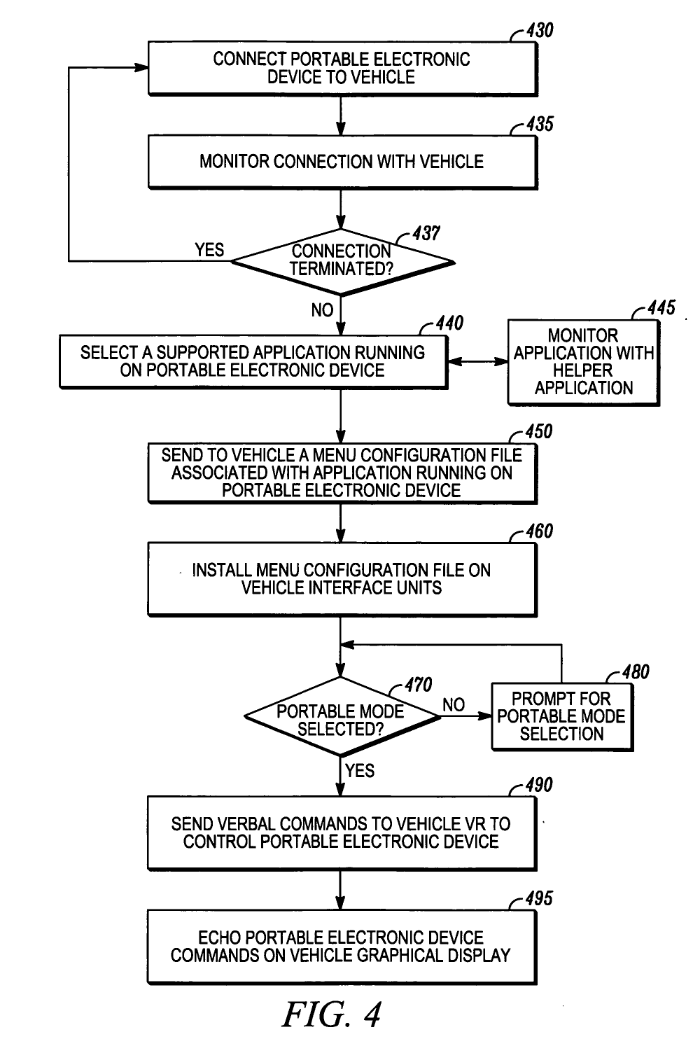

FIG. 4 illustrates another example of one embodiment of the present invention where steps are taken to a HMI system for a portable electronic device. After the user connects the portable electronic device 210 to the vehicle interface unit 220, at step 430, the vehicle interface unit 220 may monitor, at step 435, the connection between the portable electronic device and the vehicle interface unit. If the connection becomes terminated, the vehicle interface unit 220 may attempt, at step 437, to re-establish a connection with the portable electronic device 210, or the portable electronic device 210 may attempt, at step 430, to re-establish a connection with the vehicle interface unit 220. Either the vehicle interface unit 220 or the portable electronic device 210 may alert the user that the connection has terminated. The alert may be accomplished with an audible or visual signal to the user.

After the user selects a supported application on the portable electronic device at step 440, the helper application may thereafter monitor, at step 445, the supported application. The helper application may monitor the supported application for data transfer rates, stability, or communication statistics to maintain a robust and functional interface. In addition, when the user sends verbal commands to the vehicle interface unit 220, at step 490, to control the portable electronic device 210, the vehicle interface unit 220 may echo, at step 495, the verbal commands by displaying a visual representation of the verbal commands on a visual display of the vehicle interface unit 220. The vehicle interface unit 220 may also transmit an audible confirmation of the verbal commands, such as by repeating the commands.

The sequences of FIGS. 3-4 may be encoded in a signal bearing medium, a computer readable medium such as a memory, programmed within a device such as one or more integrated circuits, or processed by a controller or a computer. If the methods are performed by software, the software may reside in a memory resident to or interfaced to the device, a communication interface, or any other type of non-volatile or volatile memory interfaced or resident to the network logic. The memory may include an ordered listing of executable instructions for implementing logical functions. A logical function may be implemented through digital circuitry, through source code, through analog circuitry, or through an analog source such as through an analog electrical, audio, or video signal. The software may be embodied in any computer-readable or signal-bearing medium, for use by, or in connection with an instruction executable system, apparatus, or device. Such a system may include a computer-based system, a processor-containing system, or another system that may selectively fetch instructions from an instruction executable system, apparatus, or device that may also execute instructions.

A “computer-readable medium,” “machine-readable medium,” “propagated-signal” medium, and/or “signal-bearing medium” may comprise any unit that contains, stores, communicates, propagates, or transports software for use by or in connection with an instruction executable system, apparatus, or device. The machine-readable medium may selectively be, but not limited to, an electronic, magnetic, optical, electromagnetic, infrared, or semiconductor system, apparatus, device, or propagation medium. A non-exhaustive list of examples of a machine-readable medium would include: an electrical connection “electronic” having one or more wires, a portable magnetic or optical disk, a volatile memory such as a Random Access Memory “RAM” (electronic), a Read-Only Memory “ROM” (electronic), an Erasable Programmable Read-Only Memory (EPROM or Flash memory) (electronic), or an optical fiber (optical). A machine-readable medium may also include a tangible medium upon which software is printed, as the software may be electronically stored as an image or in another format (e.g., through an optical scan), then compiled, and/or interpreted or otherwise processed. The processed medium may then be stored in a computer and/or machine memory.

From the foregoing, it can be seen that the present invention provides a system for implementing a vehicle-based VR-based HMI for a portable electronic device. The vehicle VR HMI may be integrated with current telematics units in vehicle and may also require supporting updates to vehicle “head end” units and small application changes in the portable electronic device software. The application provides a system that is adaptable to changing software requirements in a portable electronic device, so that a vehicle interface unit may be configured at run-time for new applications.

While various embodiments of the invention have been described, it will be apparent to those of ordinary skill in the art that many more embodiments and implementations are possible within the scope of the invention. Accordingly, the invention is not to be restricted except in light of the attached claims and their equivalents.

1. A method for interfacing a portable electronic device with a vehicle interface unit comprising:
configuring the vehicle interface unit in the vehicle to support adding at least one new menu, where the at least one menu is created by the vehicle interface unit and provides interface functions to allow interaction with the portable electronic device;
receiving the portable electronic device as an input to the vehicle interface unit;
receiving at least one application from the portable electronic device, where the at least one application is running on the portable electronic device;
receiving a menu configuration file from the portable electronic device, where the menu configuration file is associated with the supported application running on the portable electronic device; and
receiving one or more verbal commands, where the verbal commands comprise a set of instructions to control the portable electronic device.

2. The method of claim 1 further comprising installing a helper application on the portable electronic device to allow the portable electronic device to function as a helper device, where the helper application monitors the supported application running on the portable electronic device.

3. The method of claim 1 further comprising:
installing, on the vehicle interface unit, the menu configuration file sent from the portable electronic device; and
selecting, through the vehicle interface unit, a mode of operation of the vehicle interface unit to indicate a portable mode, where the portable mode indicates the vehicle interface unit is configured to accept commands from the portable electronic device.

4. The method of claim 1 where the connecting further comprises detecting the connection of the portable electronic device to the vehicle interface unit by the portable electronic device helper application.

5. The method of claim 1 where the vehicle interface unit comprises a voice recognition system, where the voice recognition system supports run-time addition of one or more new menus contained in the menu configuration file.

6. The method of claim 1 where connecting further comprises connecting the portable electronic device to the vehicle interface unit via a wireless connection or wired connection.

7. The method of claim 5 where the voice recognition system further comprises a text-to-speech (TTS) system.

8. The method of claim 1 further comprising displaying a text translation of the verbal commands on a graphical display unit provided with the vehicle interface unit.

9. The method of claim 1 where sending the menu configuration file occurs only when a new supported application is loaded on the portable electronic device.

10. The method of claim 1 where the portable electronic device is selected from the group consisting of: a personal digital assistant (PDA), a notebook computer, and a wireless-enabled cellular telephone.

11. A system for implementing a human-machine-interface in a vehicle comprising:
a vehicle interface unit located in the vehicle;
a portable electronic device located within the vehicle, where the portable electronic device is configured for interfacing with the vehicle, and in communication with the vehicle interface unit, and where the portable electronic device is configured with a helper application for interfacing with the vehicle interface unit;
a memory within the portable electronic device for storing one or more applications and one or more menu configuration files;
a memory within the vehicle interface unit for storing one or more menu configuration files; and
a voice recognition system, where the voice recognition system supports run-time addition of one or more new menus contained in the menu configuration file.

12. The system of claim 11 further comprising a graphical display unit coupled with the vehicle interface unit.

13. The system of claim 11 further comprising a wireless or wired connection between the portable electronic device and the vehicle interface unit.

14. The system of claim 11 where the voice recognition system further comprises a text-to-speech (TTS) system.

15. The system of claim 11 where the portable electronic device is selected from the group consisting of: a portable digital assistant (PDA), a notebook computer, and a wireless-enabled cellular telephone.

16. A method for implementing a human-machine interface with a portable electronic device comprising:
configuring the vehicle interface unit to support adding one or more new menus, where the menus are created by the vehicle interface unit and provide interface functions to allow interaction with the portable electronic device;
connecting the portable electronic device to the vehicle interface unit;
executing one or more applications on the portable electronic device;
sending, from the portable electronic device, a menu configuration file stored in the memory of the portable electronic device, where the menu configuration file is associated with the supported application running on the portable electronic device; and
sending one or more verbal commands, where the verbal commands comprise a set of instructions to control the portable electronic device.

17. The method of claim 16 further comprising installing a helper application on the portable electronic device to allow the portable electronic device to function as a helper device.

18. The method of claim 17 further comprising:
installing, on the vehicle interface unit, the menu configuration file sent from the portable electronic device; and
selecting a mode of operation of the vehicle interface unit to indicate a portable mode, where the portable mode indicates the vehicle interface unit is configured to accept commands from the portable electronic device.

19. The method of claim 18 where the method is adapted for use with a vehicle voice recognition system.

20. An apparatus for implementing a human-machine interface in a vehicle comprising:
interface means for implementing one or more new menus, where the menus create one or more interface functions to allow interaction with a portable electronic device;
means for receiving verbal instructions;
means for storing one or more applications and one or more menu configuration files in the portable electronic device;
means for storing one or more menu files, where the menu files are generated based on the menu configuration files; and
means for sending commands to the portable electronic device, where the commands execute the applications in the portable electronic device.
